(19) United States
(12) Patent Application Publication
(10) Pub. No.: US 2008/0012099 A1
(43) Pub. Date: Jan. 17, 2008

(54) Electronic assembly and manufacturing method having a reduced need for wire bonds

(76) Inventors: Shing Yeh, Kokomo, IN (US); Steven A. Middleton, Cicero, IN (US)

Correspondence Address: DELPHI TECHNOLOGIES, INC., M/C 480-410-202, PO BOX 5052, TROY, MI, 48007, US

(21) Appl. No.: 11/484,501

(22) Filed: Jul. 11, 2006

(51) Int. Cl. H01L 23/495

(52) U.S. Cl. 257/666

(57) ABSTRACT

An electronics assembly having a reduced need for wire bonds is provided. The electronics assembly includes a substrate having upper and lower surfaces. An electronic circuit device having conducting pads is attached to the upper surface of the substrate such that the conducting pads face the upper surface of the substrate. The lower surface of the substrate includes an exposed conducting feature. An electrically conducting interconnect in the substrate electrically couples the exposed conducting feature to the conducting pads of the electronic circuit device. The exposed conducting feature of the substrate is electrically coupled to a leadframe finger of a leadframe by solder, providing a conducting path between the leadframe finger and the electronic circuit device.

### TECHNICAL FIELD

The present invention is generally directed to electronic assemblies and electronic assembly manufacturing methods, and, more specifically, to vehicle electronics modules and a method for manufacturing vehicle electronics assemblies in which the need for wire bonds is reduced or eliminated.

### BACKGROUND OF THE INVENTION

Vehicle electronics assemblies, sometimes referred to as modules, have been increasingly employed in vehicles to provide various vehicle control and convenience functions. Examples of vehicle control systems that have employed vehicle electronics modules include engine control systems, transmission control systems, vehicle stability systems, and airbag control systems, ignition control systems, speed control systems and emission control systems, among others. Some of the vehicle convenience systems that have employed electronics modules include vehicle audio systems, heating, ventilation and air conditioning (HVAC) systems, power window and door lock controls, and vehicle telematics systems, among others.

Wire bonding technology is typically used in electronics modules, including vehicle electronics modules, as one method for making electrical connections between components used in the modules and leadframes and/or circuit boards. Typical electronics modules and/or packages also utilize other packaging and interconnect technologies to connect electronics components such as, for example, epoxy and solder connections, welding, and discrete component connection.

Assembly processes employing wire bonding typically involve multiple steps. Initially, circuit components are attached to a substrate, often using an adhesive. The circuit components typically include conductive structures, often referred to as bond pads, on the surface of the circuit component that remain exposed after being bonded to the substrate. Next, the substrate is attached to a metallic leadframe using solder and/or epoxy. The conducting structures on the surface of the circuit component typically remain exposed after this step. Finally, a wire bonding process is used to make electrical connections between the exposed conducting structures on the surface of the circuit component and individual leads of the leadframe. The wire bonds typically have the appearance of tiny wires running from the individual leadframe fingers to the various conducting structures on the surface of the circuit component. In this manner, electrical signals can be provided from the individual leadframe fingers to the circuit component, and vice-versa.

FIG. 1 generally illustrates a conventional electronic assembly that has been formed in the manner generally known in the art. As shown, electronics assembly 80 includes a circuit chip 82 that has been attached to the surface of a substrate 84 using an adhesive. As shown, circuit chip 82 includes multiple conductive pads 86, also generally known as bond pads. Each of conductive pads 86 is connected to circuitry located in or on circuit chip 82, and serves to provide an electrical connection between the surface of conductive pads 86 and the electrical circuitry in or on circuit chip 82. Substrate 84, with circuit chip 82 bonded to its surface, is shown attached to a die paddle (not shown) of a leadframe having multiple leadframe fingers 94. Substrate 84 is attached to the leadframe by an epoxy or solder. As shown, conductive pads 86 that remain exposed on the surface of circuit chip 82 after circuit chip 82 has been bonded to substrate 84 and substrate 84 has been bonded to the leadframe, are electrically coupled to leadframe fingers 94 by means of multiple wire bonds 96. In this manner, electronic signals that are provided at leadframe fingers 94 are conducted from leadframe fingers 94 through wire bonds 96 to conductive pads 86, and from conductive pads 86 to circuitry located in or on circuit chip 82. In this manner, signals provided at leadframe fingers 94 are provided to circuitry in or on circuit chip 82, and vice versa. As can be seen from FIG. 1, wire bonds 96 are thin, metallic wires, stretching from leadframe fingers 94 to the surface of conductive pads 86.

In automotive electronics, cost, size, performance, and reliability are among the factors that are typically considered when evaluating technologies for use in electronics module manufacturing. Although wire bonding can provide adequate performance in vehicle electronics modules, its material cost, manufacturing cost, reliability, and size implications can make it less than an optimal interconnect solution. For example, because (as noted above) wire bonding is typically a sequential process, carried out after earlier process steps have been completed, it often adds processing steps to the manufacturing process, increasing the time required to produce an electronics module or assembly. In addition, adding a wire bonding step to a manufacturing process typically requires additional equipment and manufacturing floor space. Further, due to the small size of the wire bonds and their fragile nature, reliability of the wire bonds can be a concern.

What is needed is an electronics assembly in which factors such as cost, size, and manufacturing cycle times associated with interconnections between components of the electronics assembly can be reduced while providing for reliable connections among the components.

### SUMMARY OF THE INVENTION

In accordance with one aspect of the present invention, an electronics assembly is provided. The electronics assembly includes a substrate having upper and lower surfaces. An electronic circuit device having conducting pads is attached to the upper surface of the substrate such that the conducting pads face the upper surface of the substrate. The lower surface of the substrate includes an exposed conducting feature. An electrically conducting interconnect in the substrate electrically couples the exposed conducting feature to the conducting pads of the attached electronic circuit device. The exposed conducting feature of the substrate is electrically coupled to a leadframe finger of a leadframe, providing an electrically conducting path between the leadframe finger and the electronic circuit device.

In accordance with another aspect of the present invention, a method for forming an electronics assembly is provided. The method includes the steps of providing a substrate with an exposed upper electrically conducting feature on its upper surface and an exposed lower electrically conducting feature on its lower surface. The upper and lower electrically conducting features are electrically joined through the substrate by an electrically conducting interconnect. The method further includes the steps of providing an electronic circuit device with a conducting pad on one of its surfaces, depositing solder on the upper electrically conducting feature of the substrate, positioning the conducting pad in contact with the solder, and heating the solder to join the upper electrically conducting feature of the substrate to the conducting pad of the electronic circuit device. The method still further includes the steps of providing a leadframe assembly having multiple leadframe fingers, depositing solder on a leadframe finger, positioning the leadframe finger and the lower electrically conducting feature adjacent to each other, and heating the solder to join the leadframe finger and lower electrically conducting feature to provide an electrically conducting path from the leadframe finger to the electronic circuit device.

In accordance with yet another aspect of the present invention, an electronics assembly is provided including a substrate having upper and lower surfaces and a flip-chip electronic circuit device. The flip-chip electronic circuit device has electronic circuitry and conducting pads configured to provide electronic signals from the conducting pads to the electronic circuitry electrically coupled to the upper surface of the substrate, such that the conducting pads face the upper surface of the substrate. The lower surface of the substrate includes an exposed conducting feature. An electrically conducting interconnect traveling through the substrate electrically couples the exposed conducting feature to the conducting pads of the attached flip-chip electronic circuit device. The exposed conducting feature of the substrate is electrically coupled to a leadframe finger of a leadframe, providing a conducting path from the leadframe finger, through the electrically conducting interconnect, to the pad of the flip-chip electronic circuit device that is coupled to the upper surface of the substrate.

These and other features, advantages, and objects of the present invention will be further understood and appreciated by those skilled in the art by reference to the following specification, claims, and appended drawings.

### BRIEF DESCRIPTION OF THE DRAWINGS

The present invention will now be described, by way of example, with reference to the accompanying drawings, in which:

FIG. 1 is a perspective elevated view of a conventional electronics assembly that is generally known.

FIG. 2 is a perspective top view of an electronics assembly, according to a first embodiment of the present invention;

FIG. 3 is a cross-sectional view taken through line II-II of FIG. 2;

FIG. 4 is an enlarged exploded view of section IV of FIG. 3;

FIG. 5 is a cross-sectional view taken through line III-III of FIG. 2;

FIG. 6 is a perspective top view of an electronics assembly, according to a second embodiment of the present invention;

FIG. 7 is a cross-sectional view taken through line V-V of FIG. 6;

FIG. 8 is a cross-sectional view taken through line VI-VI of FIG. 6; and

FIGS. 9A-9J are perspective views of an electronics assembly in various stages of manufacture, generally illustrating a method for manufacturing an electronics assembly according to one embodiment of the present invention.

### DESCRIPTION OF THE PREFERRED EMBODIMENTS

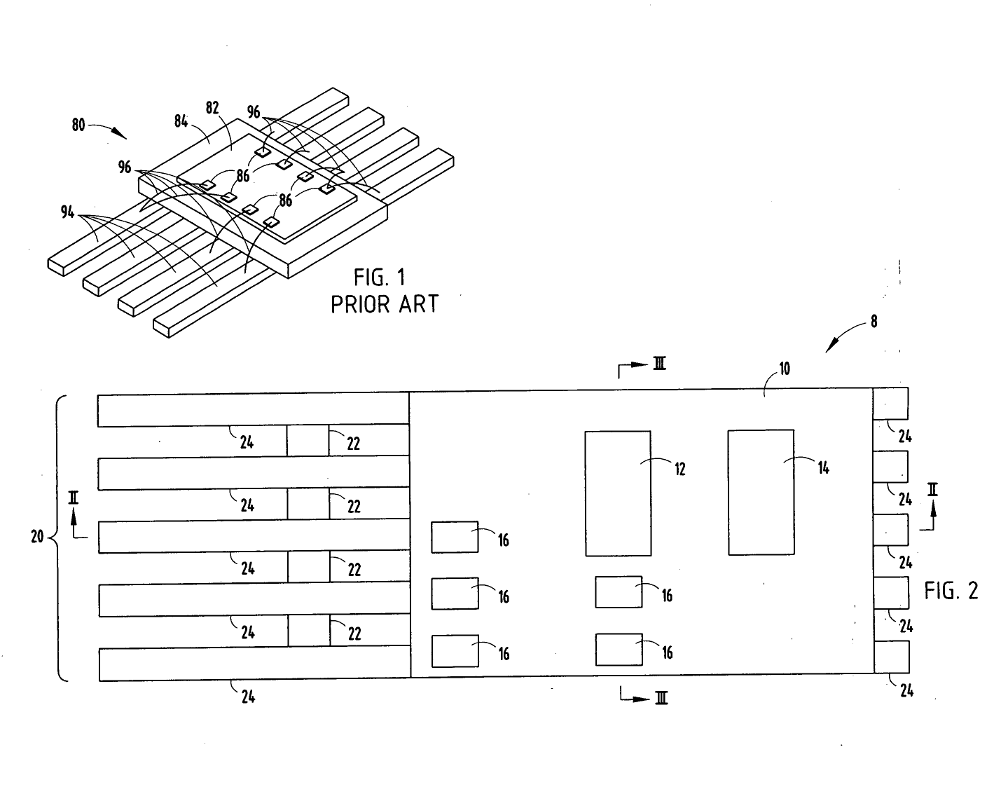

Referring now to FIGS. 2-5, an electronics assembly 8 is generally illustrated according to a first embodiment of the present invention. As shown, electronics assembly 8 includes a substrate 10 to which multiple electronic components are attached. In one embodiment, electronics assembly 8 is a vehicle electronics assembly located in and electrically couple to a vehicle and configured to perform vehicle control and/or vehicle convenience functions. In one exemplary embodiment, the electronics assembly 8 is an integrated vehicle ignition module, and is configured to process vehicle ignition signals. In the embodiment shown, substrate 10 is a double-sided printed circuit board (PCB). Double-sided PCBs differ from single-sided PCBs, in that single-sided PCBs typically only have circuit patterns printed or formed on one side of the PCB. Double-sided PCBs, on the other hand, are capable of having circuit patterns printed or formed on both sides of the PCB. According to one embodiment, substrate 10 is made of an epoxy material reinforced with a woven fiberglass mat commonly used in manufactured PCBs, and known as FR-4. It should be appreciated that in alternative embodiments, substrate 10 could be made of other materials commonly used in the manufacture of PCBs, such as, for example, a ceramic, e.g. LTCC.

As shown, substrate 10 includes multiple electrically conducting interconnects 30, traveling from the upper surface of substrate 10 through substrate 10 to the lower surface of substrate 10. Electrically conducting interconnects 30 are formed of a conducting material, such as, for example, copper. As shown, electrically conducting interconnects 30 are metallic vias formed of copper. It should be appreciated that the upper surfaces of electrically conducting interconnects 30 are exposed on the upper surface of substrate 10. These exposed upper surfaces are referred to herein as upper electrically conducting features 26. It should also be appreciated that the lower surfaces of electrically conducting interconnects 30 are exposed on the lower surface of substrate 10. These exposed lower surfaces are referred to herein as lower electrically conducting features 28. As shown, electrically conducting interconnects 30 provide an electrically conducting path from various upper electrically conducting features 26 on the upper surface of substrate 10 to various lower electrically conducting features 28 on the lower surface of substrate 10. In an alternate embodiment, upper electrically conducting features 26 and lower electrically conducting features 28 are conductive circuits, such as, for example, conducting pads, formed on the upper and lower surfaces of substrate 10, respectively. Upper electrically conducting features 26 and lower electrically conducting features 28 are electrically coupled to each other by means of an electrically conducting interconnect 30 traveling between upper electrically conducting features 26 and lower electrically conducting features 28 through substrate 10. In yet another alternate embodiment, at least one upper electrically conducting feature 26 is a surface of an electrically conducting interconnect 30 that is exposed on the upper surface of substrate 10, and at least one lower electrically conducting feature 28 is a surface of an electrically conducting interconnect 30 that is exposed on the lower surface of substrate 10.

Substrate 10 is also shown having multiple electronic circuit devices 12, 14, and 16 attached to its upper surface. In the embodiment shown, electronic circuit device 12 is a logic integrated circuit (IC), electronic circuit device 14 is a power IC, and electronic circuit devices 16 are discrete electronic components, such as, for example, resistors, capacitors, diodes, inductors and transistors. In an alternate embodiment, electronic circuit device 12 is a memory integrated circuit or an integrated circuit comprising both memory and logic. It should be appreciated that in yet another alternate embodiment, multiple electronic circuit devices 12 may be attached to substrate 10. Electrically conducting areas, such as pad 35, of discrete electronic components 16 are attached to various upper electrically conducting features 26 of substrate 10 by means of solder paste 32. In an alternate embodiment, the electrically conducting areas are leads. Solder paste 32 acts to secure discrete electronic components 16 to the upper surface of substrate 10, and also serves to provide a conducting path between discrete electronic components 16 and upper electrically conducting features 26. It should be appreciated that electronic signals provided at lower electrically conducting features 28 are conducted through electrically conducting interconnects 30, through upper electrically conducting features 26, and into discrete electronic components 16 that have been electrically coupled to upper electrically conducting features 26 by means of solder paste 32.

Substrate 10 is also shown having logic IC 12 secured to its upper surface. According to one embodiment, logic IC 12 is a flip-chip logic IC. As such, logic IC 12 has solder beads, also known as solder bumps or solder balls, deposited onto conductive pads (not shown) on its surface. The solder beads and/or solder balls operate to conduct electronic signals applied to the solder beads and/or solder balls into electronic circuitry in logic IC 12 through the conductive pads. As shown, some of the solder beads and/or solder balls on the surface of logic IC 12 are attached to the upper surface of substrate 10 by means of solder paste 32.

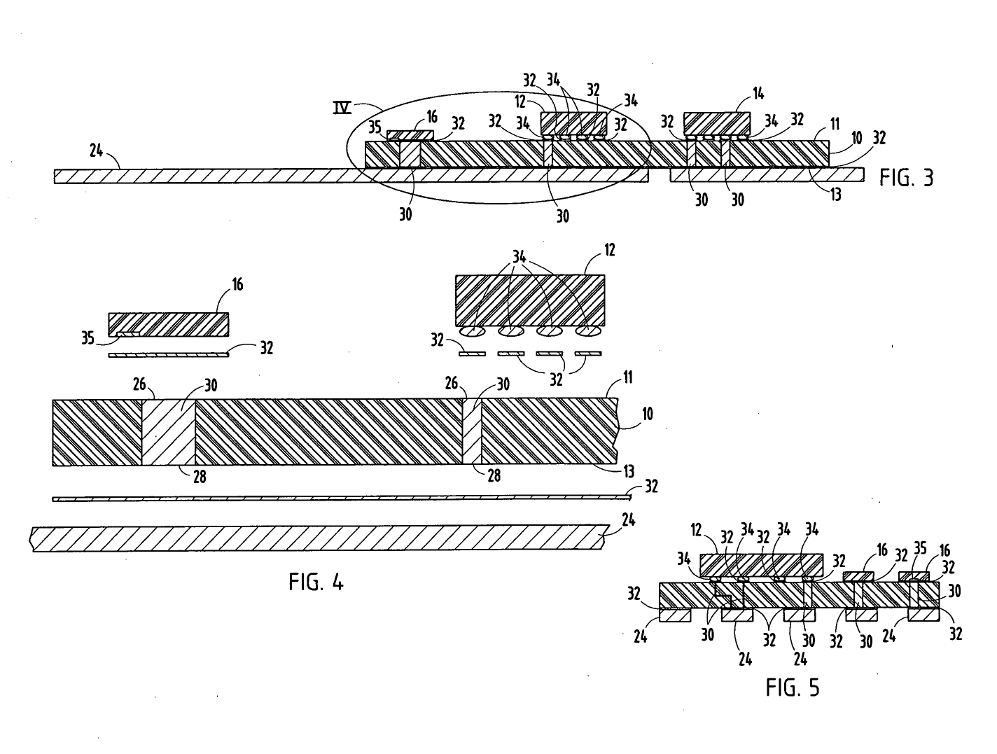

As best seen in FIG. 3, some of the solder bumps 34 are soldered to upper electrically conducting features 26 of substrate 10. It should be appreciated that solder bumps 34 that have been soldered to upper electrically conducting features 26 act to conduct electrical signals between upper electrically conducting features 26 and electronic circuitry within logic IC 12. It should also be appreciated that where solder bumps 34 are electrically connected to upper electrically conducting features 26, signals provided at lower electrically conducting features 28 coupled to those upper electrically conducting features 26 by electrically conducting interconnect 30 will be conducted from lower electrically conducting features 28, through the electrically conducting interconnect 30 and upper electrically conducting features 26, through solder paste 32 and solder bumps 34, into the conductive pads of logic IC 12, and ultimately, to electronic circuitry in logic IC 12. In the same manner, signals provided by logic IC 12 will be provided to corresponding lower electrically conducting features 28. As noted above, in alternate embodiments, electronic circuit device 12 may be a memory IC or an IC comprising both memory and logic. In yet other alternate embodiments, multiple electronic circuit devices 12 may be electrically coupled to substrate 10 as discussed above.

Substrate 10 is also shown including a power IC 14. According to one exemplary embodiment, power IC 14 is an Integral Gated Biased Transistor (IGBT) integrated circuit. According to an alternate embodiment, a smart power or Field Effect Transistor (FET) is utilized in place of power IC 14. In the present embodiment, power IC 14 is a flip-chip electronic circuit device that is attached to the upper surface of substrate 10 in the same manner discussed above with respect to logic IC 12. In this embodiment, power IC 14 has multiple solder bumps 34 coupled to upper electrically conducting features 26 by means of solder paste 32. As discussed above with respect to logic IC 12, electronic signals travel from lower electrically conducting features 28 to electronic circuitry in power IC 14 by means of electrically conducting interconnects 30, upper electrically conducting features 26, and the solder bumps 24 coupled to upper electrically conducting features 26 by solder paste 32.

Substrate 10 is also shown coupled to a leadframe 20. The leadframe 20 includes leadframe fingers 24 and dam bars 22. Leadframe 20 may be made from a conductive copper alloy. It should be appreciated that in alternate embodiments, leadframe 20 could also be made from other metals or conductive metal alloys. As best seen in FIGS. 3-5, a lower surface 13 of substrate 10 is coupled to various leadframe fingers 24 by means of solder paste 32. More specifically, with reference to FIG. 4, multiple lower electrically conducting features 28 are electrically coupled to leadframe fingers 24 by means of solder paste 32. In areas where lower electrically conducting features 28 have been electrically coupled to leadframe fingers 24, it should be appreciated that electronic signals applied to leadframe fingers 24 travel through solder paste 32 to lower electrically conducting features 28, and from lower electrically conducting features 28 through corresponding electrically conducting interconnects 30 and upper electrically conducting features 26 to logic IC 12, power IC 14, and discrete electronic components 16. It should be appreciated that signals provided by logic IC 12, power IC 14, and discrete electronic components 16 travel from those components through upper electrically conducting features 26 coupled to those components, through corresponding electrically conducting interconnects 30 and lower electrically conducting features 28, and on to the corresponding leadframe fingers 24 to which those lower electrically conducting features 28 have been electrically coupled by solder paste 32. It should also be appreciated that signals provided by logic IC 12, power IC 14, and discrete electronic components 16 can travel to corresponding leadframe fingers 24 and devices coupled to those leadframe fingers 24. Conductive pads of logic IC 12, power IC 14, and discrete electronic components 16 are electrically coupled to leadframe fingers 24 without the use of wire bonding, obviating the need for an additional wire bonding step, and providing for reliable connections between the conductive pads and the leadframe fingers 24. As shown in FIGS. 34, multiple lower electrically conducting features 28 and upper electrically conducting features 26 can be connected to the same leadframe finger 24.

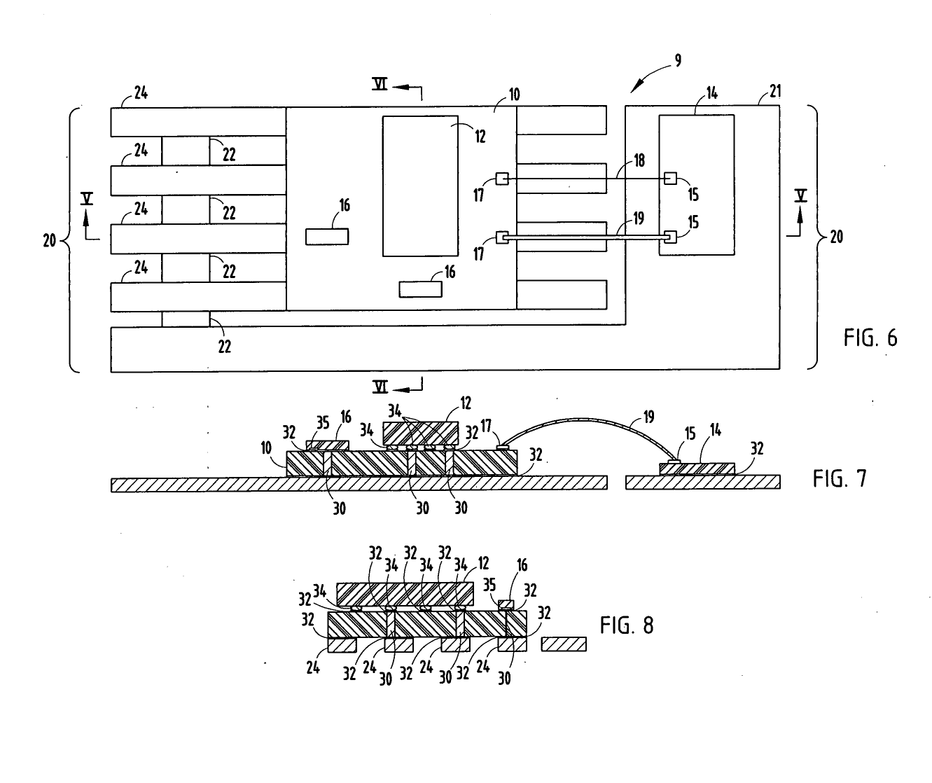

Referring to FIGS. 6-8, an electronics assembly 9 is generally illustrated, according to a second embodiment of the present invention. As described above with respect to the first embodiment generally illustrated in FIGS. 2-5, the electronics assembly 9 of the second embodiment includes a substrate 10 to which multiple electronic circuit devices are attached. However, in the second embodiment, power IC 14 is not attached to the substrate 10. Substrate 10 includes multiple upper electrically conducting features 26, multiple lower electrically conducting features 28, and multiple electrically conducting interconnects 30 electrically coupling upper electrically conducting features 26 to lower electrically conducting features 28.

Substrate 10 is also shown having logic IC 12 and discrete electronic components 16 attached to its upper surface. Logic IC 12 and discrete electronic components 16 are attached to the upper surface of substrate 10 in the same manner as described above with respect to the first embodiment of the present invention generally illustrated in FIGS. 2-5. Upper electrically conducting features 26, lower electrically conducting features 28, and electrically conducting interconnects 30 function in the same manner described above with respect to the first embodiment of the present invention to provide signals provided at lower electrically conducting features 28 to logic IC 12 and discrete electronic components 16 and vice versa.

The lower surface of substrate 10 is shown attached to a leadframe 20. Substrate 10 is attached to leadframe 20 in a manner similar to that discussed above with respect to the first embodiment of the present invention. Leadframe 20 is also shown having dam bars 22 and a die attach pad 21. As with the first embodiment, lower electrically conducting features 28 are connected to leadframe fingers 24 by means of solder paste 32. In this manner, electrical signals provided at leadframe fingers 24 are conducted from the leadframe fingers 24 into lower electrically conducting features 28 through electrically conducting interconnects 30 to upper electrically conducting features 26. From upper electrically conducting features 26, electronic signals are provided to logic IC 12 and/or discrete electronic components 16. The electronics assembly of the second embodiment differs from that of the first embodiment in that power IC 14 is not attached to substrate 10. Instead, power IC 14 is attached to die attach pad 21 by means of an adhesive.

Substrate 10, according to the second embodiment, is also shown having conductive pads 17, also known as bond pads, located on the upper surface of substrate 10. Bond pads 17 are electrically coupled to other circuitry located in or on substrate 10 by means of conductive traces in substrate 10, or on the surface of substrate 10 (not shown). Power IC 14 is shown having conductive pads 15, also known as bond pads, located on its surface. Conductive pads 15 are configured to provide a conducting path from the surface of the conducting pads 15 to circuitry within power IC 14. It should be appreciated that power IC 14 of the first embodiment described above also included conductive pads. However, in the first embodiment, the conductive pads were facing downward, and had solder balls attached to their surfaces for attaching power IC 14 to the surface of substrate 10.

In the second embodiment, electronics assembly 9 is shown having a wire bond 18 and a solder bar bond 19 electrically connecting bond pads 17 of substrate 10 to conductive pads 15 of power IC 14. In this manner, electronic signals can be provided from substrate 10 to power IC 14 and vice versa. It should be appreciated that the assembly 9 of the second embodiment provides for the electrical connection of logic IC 12 and discrete electronic components 16 mounted on the surface of substrate 10 to leadframe fingers 24 without requiring the use of wire bonding to electrically connect these components. The assembly 9 of the second embodiment also provides for the electrical connection of power IC 14 to substrate 10 by means of wire bonding. By providing a separate die attach pad 21 for power IC 14, thermal energy associated with power IC 14 can be more easily isolated from substrate 10 and the circuitry coupled to substrate 10.

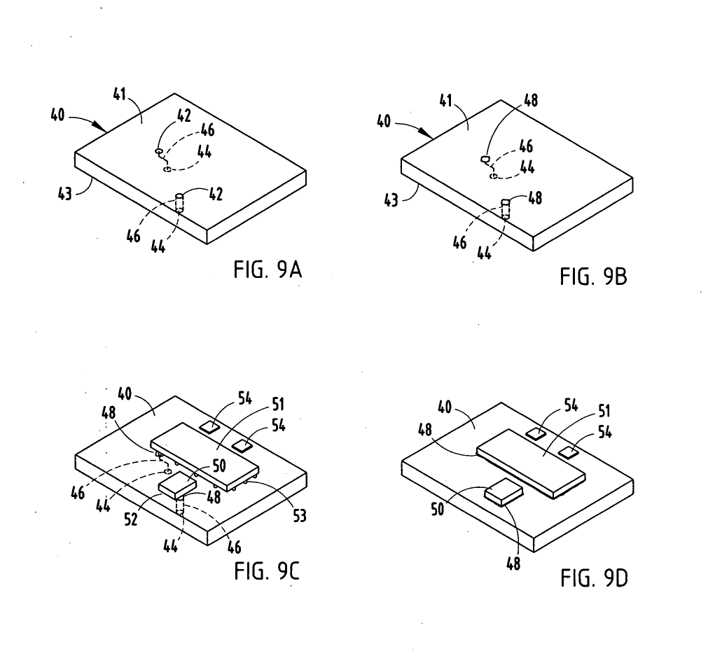

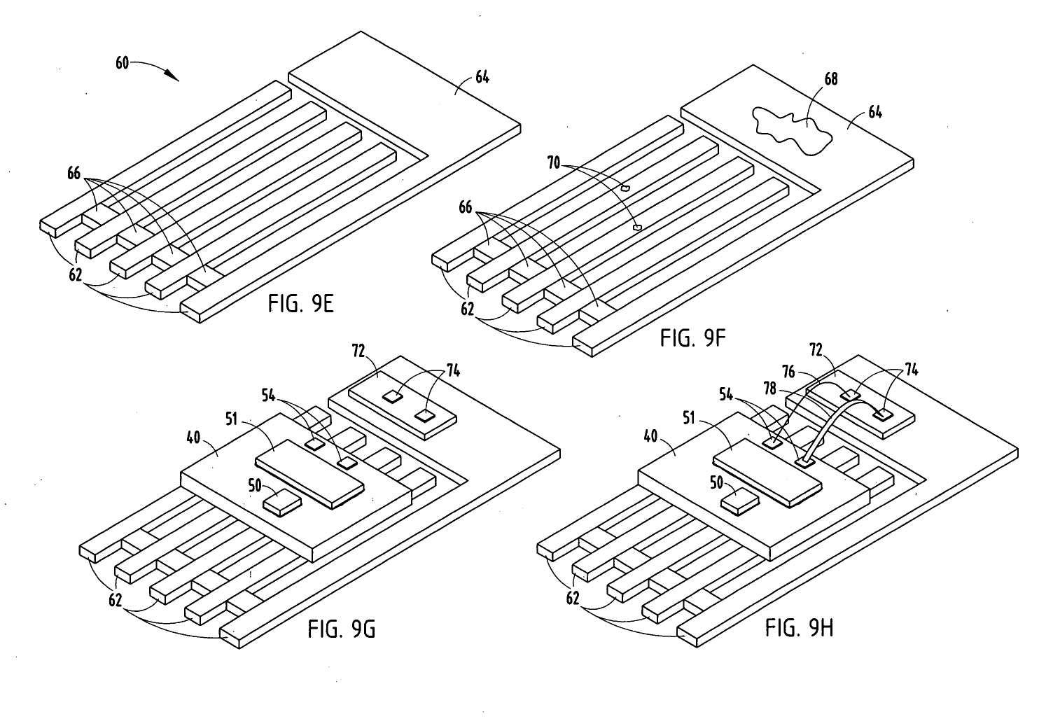

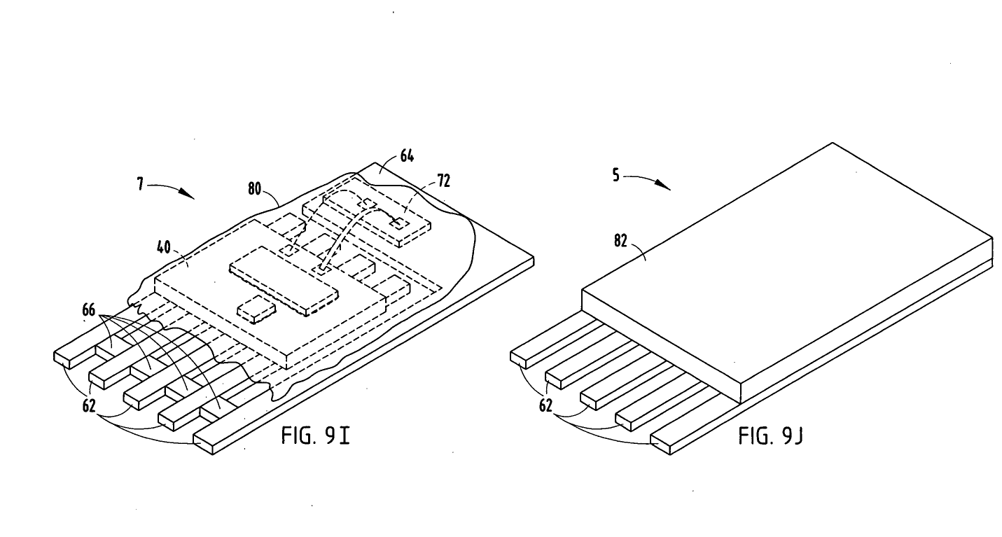

FIGS. 9A-9J generally illustrate a method 100 for making an electronics assembly, according to one embodiment of the present invention. Referring to FIG. 9A, a substrate 40 is provided in a first step 102 of the method. Substrate 40 includes an upper surface 41, a lower surface 43, upper electrically conducting features 42, lower electrically conducting features 44, and electrically conducting interconnects 46. Electrically conducting interconnects 46 electrically couple upper electrically conducting features 42 and lower electrically conducting features 44. Electrically conducting interconnects 46 are electrically conducting vias that may be formed from copper or other suitable electrically conducting mediums. In one embodiment, substrate 40 is a PCB substrate that may be made of FR-4. Substrate 40 may be made of alternative material used for PCB substrates, such as, for example, ceramic.

Referring to FIG. 9B, solder paste 48 is deposited on the surface of upper electrically conducting features 42 in a second step 104 of the method, such that the solder paste 48 at least partially overlaps the surface of upper electrically conducting features 42.

Referring to FIG. 9C, electronic circuit devices 50 and 51 are placed on the surface of substrate 40 in a third step 106 of the method 100, such that conducting features on the lower surfaces of electronic circuit devices 50 and 51 are in contact with the solder paste 48 deposited in the previous step. The electronic circuit device 50 may be a discrete electronic component having conductive pads (not shown) located on its lower surface. Discrete electronic component 50 is positioned such that at least one conductive pad is positioned in contact with the solder paste 48 deposited in the previous step. In one embodiment, electronic circuit device 51 is a logic IC having conductive solder balls 53 joined to conductive pads (not shown) located on its lower surface. Logic IC 51 is positioned such that at least one solder ball on its lower surface is in contact with the solder paste 48 deposited in the previous step.

FIG. 9D generally illustrates the substrate resulting from steps 102-106 of the method 100 after a solder reflow process has been completed in a fourth step 108, causing the solder paste 48 to melt and electrically couple discrete electronic component 50 and logic IC 51 to the upper electrically conducting features 42 of substrate 40. At this point in the method, it should be appreciated that electronic signals applied to lower electrically conducting features 44 would travel through corresponding electrically conducting interconnects 46 to the corresponding upper electrically conducting features 42, and on to logic IC 51 and discrete electronic component 50, which have been electrically coupled to upper electrically conducting features 42 by means of melted solder paste 48.

Referring to FIG. 9E, a leadframe 60 is provided in the next step 110 of the method 100. As shown, leadframe 60 includes leadframe fingers 62, dam bars 66, and die attach pad 64. The leadframe 60 may be formed from copper. In an alternative embodiment, leadframe 60 may be formed from a metal other than copper, or from a metal alloy.

FIG. 9F generally illustrates a fifth step 112 of the method 100, in which solder paste 70 is applied to various leadframe fingers 62, and an adhesive 68 is applied to die attach pad 64. In the next step 114 of the method, generally illustrated in FIG. 9G, the substrate assembly resulting from the steps generally illustrated in FIGS. 9A-9F is positioned adjacent to leadframe fingers 62, such that the lower electrically conducting interconnects 46 that are electrically coupled to logic IC 51 and discrete electronic component 50 are in contact with the solder paste 70 deposited on leadframe fingers 62 in step 112. In addition, a power IC 72 is placed adjacent to die attach pad 64, such that its lower surface is in contact with an adhesive 68 deposited in step 112. The adhesive acts to bond power IC 72 to the surface of die attach pad 64.

FIG. 9H generally illustrates the electronics assembly after a sixth reflow step 116 and a seventh wire bonding step 118 of the method 100 have been completed. As a result of the reflow step 116, substrate 40 is secured to leadframe fingers 62 by means of the solder paste 70 that was melted during the sixth reflow step 116. It should be appreciated that electronic signals provided to leadframe fingers 62 travel through leadframe fingers 62 to lower electrically conducting features 44 that are coupled to the leadframe fingers 62. The electronic signals then travel through electrically conducting interconnects 46 to corresponding upper electrically conducting features 42, and on to logic IC 51 and discrete electronic component 50. As also shown in FIG. 9H, electronic conducting features 74, also known as bond pads, that are located on the surface of power IC 72, are electrically coupled to bond pads 54 located on the upper surface of substrate 40 by means of a wire bond 76 and a solder bar bond 78 formed in wire bond step 118. The wire bond 76 and solder bar bond 78 make it possible for electrical signals to travel between power IC 72 and circuitry located in or on substrate 40.

FIG. 9I shows the resulting electronics assembly 7 after the electronics assembly resulting from the steps 102-118 generally illustrated in FIGS. 9A-9H has been coated with a poly-coating material in an eighth step 120 of the method 100. As shown, at least some of the leadframe fingers 62 remain exposed after the poly-coating step 120 has been completed. FIG. 9J generally illustrates a resulting electronics assembly 5 after the dam bars 66 joining leadframe 62 have been removed in a ninth step 122 of the method 100, and after the resulting structure has been encapsulated in a plastic material in a tenth step 124 of the method 100 to form an integrated circuit 5.

Although the steps outlined above in FIGS. 9A-9J discuss a method 100 for forming an electronics assembly that includes both a substrate 40 joined to leadframe fingers 62 and a power IC 72 attached to a separate die attach pad 64 and connected to substrate 40 by means of wire bonding, it should be appreciated that in alternate embodiments, power IC 72 is attached directly to substrate 40 and connected to leadframe fingers 62 by means of upper electrically conducting features 42, electrically conducting interconnects 46, and lower electrically conducting features 44, such that wire bonds are not needed to electrically connect power IC 72 to substrate 40, or to electronic circuit devices incorporated on, or in, substrate 40.

The invention, as described, advantageously provides for an electronics assembly and manufacturing method having a reduced need for wire bonds. Consequently, the invention provides for reduced cost, size, and manufacturing cycle times for electronics assemblies, and for improved reliability for electronics assemblies.

The above description is considered that of the preferred embodiments only. Modifications of the invention will occur to those skilled in the art, and to those who make or use the invention. Therefore, it is understood that the embodiments shown in the drawings and described above are merely for illustrative purposes, and not intended to limit the scope of the invention, which is defined by the following claims, as interpreted according to the principles of patent law, including the doctrine of equivalents.

1. An electronics assembly comprising:
a substrate having upper and lower planar surfaces;
a first electrically conducting feature exposed on the lower surface of said substrate;
a second electrically conducting feature exposed on the upper surface of said substrate;
an electronic circuit device having at least one electrically conducting area on a surface, said electronic circuit device being mounted on the upper surface of the substrate such that the at least one electrically conducting area of said electronic circuit device faces, and is in electrical contact with, said second electrically conducting feature;
a first electrically conducting interconnect in said substrate electrically connecting said electronic circuit device, said second electrically conducting feature, and said first electrically conducting feature, and providing an electrically conducting path between said first electrically conducting feature and the at least one electrically conducting area of said electronic circuit device; and
a leadframe having multiple leadframe fingers, wherein at least one leadframe finger is adjacent and directly joined to said first electrically conducting feature by solder to form an electrically conducting path between said leadframe and the at least one electrically conducting area of said electronic circuit device.

2. The electronics assembly of claim 1, wherein said first electrically conducting interconnect comprises a conductive via.

3. The electronics assembly of claim 1, wherein said electronic circuit device is a surface mount device (SMD).

4. The electronics assembly of claim 1, wherein said electronic circuit device is a flip-chip device.

5. The electronics assembly of claim 1, wherein said electronic circuit device is one of a memory circuit and a logic circuit.

6. The electronics assembly of claim 1, wherein said substrate is a double-sided printed circuit board (PCB).

7. The electronics assembly of claim 1, wherein said leadframe further comprises a leadframe die attach pad, the electronics assembly further comprising a power integrated circuit attached to said leadframe die attach pad, wherein said power integrated circuit is electrically connected to said substrate by at least one of wire bonding and solder bar bonding.

8. The electronics assembly of claim 1, wherein said electronic circuit device is a power integrated circuit.

9. A method for forming an electronics assembly comprising the steps of:
providing a substrate having upper and lower planar surfaces, at least one first electrically conducting feature exposed on the lower surface, at least one second electrically conducting feature exposed on the upper surface, and at least one first electrically conducting interconnect providing an electrically conducting path through the substrate between the first and second electrically conducting features;
depositing solder paste on the at least one second electrically conducting feature;
providing at least one electronic circuit device having at least one exposed conducting feature;
positioning an exposed conducting feature of the at least one electronic circuit device adjacent to, and in contact with, the solder paste
heating the solder paste to electrically join the at least one second electrically conducting feature to the exposed conducting feature of the at least one electronic circuit device;
providing a leadframe assembly having multiple leadframe fingers;
depositing solder paste on at least one of the at least one first electrically conducting feature and a first leadframe finger;
locating the at least one first electrically conducting feature and first leadframe finger in a position adjacent to each other; and
heating the solder paste to electrically join the at least one first electrically conducting feature to the first leadframe finger.

10. The method of claim 9, wherein the first electrically conducting feature comprises a conductive via.

11. The method of claim 9, wherein the at least one electronic circuit device is a surface mount device (SMD).

12. The method of claim 9, wherein the at least one electronic circuit device is a flip-chip device.

13. The method of claim 9, wherein the at least one electronic circuit device is one of a memory circuit and a logic circuit.

14. The method of claim 9, wherein the substrate is a double-sided printed circuit board (PCB).

15. The method of claim 9, wherein the leadframe assembly includes a die attach pad, and further including the steps of:
providing a power integrated circuit;
attaching the power integrated circuit to the leadframe die attach pad; and
electrically coupling the power integrated circuit to the substrate by one of a wire bond and solder bar bond.

16. The method of claim 9, wherein the at least one electronic circuit device is a power integrated circuit.

17. An electronics assembly comprising:
a substrate having upper and lower planar surfaces;
a flip-chip electronic circuit device comprising electronic circuitry and having at least one conducting pad on a first surface configured to provide electrical signals from said at least one conducting pad to said circuitry, said at least one conducting pad and first surface facing the upper surface of said substrate, and said at least one conducting pad being electrically coupled to said upper planar surface of said substrate;
a first electrically conducting feature exposed on the lower surface of said substrate;
a first electrically conducting interconnect traveling through said substrate and electrically coupling the at least one conducting pad of said flip-chip electronic circuit device and said first electrically conducting feature, said first electrically conducting interconnect providing an electrically conducting path between said first electrically conducting feature and the at least one conducting pad of said flip-chip electronic circuit device; and
a leadframe having multiple leadframe fingers, wherein at least one leadframe finger is adjacent and electrically coupled to said first electrically conducting feature by solder to form an electrically conducting path between at least one of said multiple leadframe fingers and the at least one conducting pad of said flip-chip electronic circuit device.

18. The electronics assembly of claim 17, wherein the electronics assembly is located in a vehicle and electrically coupled to a vehicle, and is configured to perform at least one of vehicle control functions and vehicle convenience functions.

19. The electronics assembly of claim 18, wherein the electronics assembly is configured to perform vehicle ignition control.

20. The electronics assembly of claim 1, wherein the electronics assembly is located in a vehicle and electrically coupled to a vehicle, and is configured to perform at least one of vehicle control functions and vehicle convenience functions.
